(19) United States
(12) Patent Application Publication
(10) Pub. No.: US 2019/0079873 A1
(43) Pub. Date: Mar. 14, 2019

(54) ELECTRONIC DEVICE HAVING VARIABLE RESISTANCE ELEMENT

(71) Applicants: SK hynix Inc., Gyeonggi-do (KR); Toshiba Memory Corporation, Tokyo (JP)

(72) Inventors: Yang-Kon KIM, Gyeonggi-do (KR); Ki-Seon PARK, Gyeonggi-do (KR); Bo-Mi LEE, Gyeonggi-do (KR); Won-Joon CHOI, Gyeonggi-do (KR); Guk-Cheon KIM, Gyeonggi-do (KR); Daisuke WATANABE, Tokyo (JP); Makoto NAGAMINE, Tokyo (JP); Young-Min EEH, Gyeonggi-do (KR); Koji UEDA, Tokyo (JP); Toshihiko NAGASE, Tokyo (JP); Kazuya SAWADA, Tokyo (JP)

(73) Assignees: SK hynix Inc.; Toshiba Memory Corporation

(21) Appl. No.: 16/186,231

(22) Filed: Nov. 9, 2018

Related U.S. Application Data
(62) Division of application No. 14/558,263, filed on Dec. 2, 2014, now abandoned.

(30) Foreign Application Priority Data
Aug. 11, 2014 (KR) 10-2014-0103754

(51) Int. Cl. G06F 12/0875; H01L 43/08; G11C 11/16; H01L 43/10

(52) U.S. Cl. CPC G06F 12/0875; G06F 2212/1016; G06F 2212/452; G11C 11/161; H01L 43/10; H01L 43/08

(57) ABSTRACT

An electronic device includes semiconductor memory, the semiconductor memory including an under layer; a first magnetic layer located over the under layer and having a variable magnetization direction; a tunnel barrier layer located over the first magnetic layer; and a second magnetic layer located over the tunnel barrier layer and having a pinned magnetization direction, wherein the under layer includes a first metal nitride layer having a NaCl crystal structure and a second metal nitride layer containing a light metal.

### CROSS-REFERENCE TO RELATED APPLICATION

This application is a division of U.S. patent application Ser. No. 14/558,263 filed on Dec. 2, 2014, which claims priority of Korean Patent Application No. 10-2014-0103754, entitled “ELECTRONIC DEVICE” and filed on Aug. 11, 2014. The disclosure of each of the forgoing applications is incorporated herein by reference in its entirety.

### TECHNICAL FIELD

This patent document relates to memory circuits or devices and their applications in electronic devices or systems.

### BACKGROUND

Recently, as electronic devices or appliances trend toward miniaturization, low power consumption, high performance, multi-functionality, and so on, there is a demand for electronic devices capable of storing information in various electronic devices or appliances such as a computer, a portable communication device, and so on, and research and development for such electronic devices have been conducted. Examples of such electronic devices include electronic devices which can store data using a characteristic switched between different resistant states according to an applied voltage or current, and can be implemented in various configurations, for example, an RRAM (resistive random access memory), a PRAM (phase change random access memory), an FRAM (ferroelectric random access memory), an MRAM (magnetic random access memory), an E-fuse, etc.

### SUMMARY

The disclosed technology in this patent document includes memory circuits or devices and their applications in electronic devices or systems and various implementations of an electronic device, in which an electronic device can improve characteristics of a variable resistance element.

In one aspect, an electronic device includes semiconductor memory, and the semiconductor memory includes an under layer; a first magnetic layer located over the under layer and having a variable magnetization direction; a tunnel barrier layer located over the first magnetic layer; and a second magnetic layer located over the tunnel barrier layer and having a pinned magnetization direction, wherein the under layer includes a first metal nitride layer having a NaCl crystal structure and a second metal nitride layer containing a light metal.

Implementations of the above electronic device may include one or more the following.

The first metal nitride layer includes a hafnium nitride layer, and the second metal nitride layer includes an aluminum nitride layer. The first metal nitride layer is located under the second metal nitride layer. The second metal nitride layer has a ZnO crystal structure, and the first magnetic layer has an Fe-BCC crystal structure or an amorphous structure. Each of the first and second metal nitride layers includes conductive material. The semiconductor memory further comprises: a magnetic correction layer which offsets a stray field created by the second magnetic layer. The magnetic correction layer is located under the under layer or over the second magnetic layer. The semiconductor memory further comprises: a capping layer located over the second magnetic layer. The capping layer includes a noble metal. The semiconductor memory further comprises: a bottom contact located under the under layer and coupled to the under layer, and wherein the first metal nitride layer of the under layer has a sidewall aligned with a sidewall of the bottom contact. The second metal nitride layer has a sidewall aligned with the sidewalls of the bottom contact and the first metal nitride layer. The first metal nitride layer has a liner shape and has an empty space inside the first metal nitride layer, and the second metal nitride layer fills the empty space. Sidewalls of the first magnetic layer, the tunnel barrier layer and the second magnetic layer are aligned with each other, and the sidewalls of the first magnetic layer, the tunnel barrier layer, and the second magnetic layer are not aligned with the sidewall of the bottom contact.

In another aspect, an electronic device includes semiconductor memory, and the semiconductor memory includes an under layer; a first magnetic layer located over the under layer and having a variable magnetization direction; a tunnel barrier layer located over the first magnetic layer; and a second magnetic layer located over the tunnel barrier layer and having a pinned magnetization direction, wherein the under layer includes a first metal nitride layer having a NaCl crystal structure and a second metal nitride layer containing a metal of atomic weight less than Ti.

In another aspect, an electronic device includes semiconductor memory, and the semiconductor memory includes an under layer; a first magnetic layer located over the under layer and having a variable magnetization direction; a tunnel barrier layer located over the first magnetic layer; and a second magnetic layer located over the tunnel barrier layer and having a pinned magnetization direction, wherein the under layer includes a first metal nitride layer having a NaCl crystal structure and a second metal nitride layer including a period 2 element metal, a period 3 element metal, or a period 4 element metal.

The electronic device may further include a microprocessor which includes: a control unit configured to receive a signal including a command from an outside of the microprocessor, and performs extracting, decoding of the command, or controlling input or output of a signal of the microprocessor; an operation unit configured to perform an operation based on a result that the control unit decodes the command; and a memory unit configured to store data for performing the operation, data corresponding to a result of performing the operation, or an address of data for which the operation is performed, wherein the semiconductor memory is part of the memory unit in the microprocessor.

The electronic device may further include a processor which includes: a core unit configured to perform, based on a command inputted from an outside of the processor, an operation corresponding to the command, by using data; a cache memory unit configured to store data for performing the operation, data corresponding to a result of performing the operation, or an address of data for which the operation is performed; and a bus interface connected between the core unit and the cache memory unit, and configured to transmit data between the core unit and the cache memory unit, wherein the semiconductor memory is part of the cache memory unit in the processor.

The electronic device may further include a processing system which includes: a processor configured to decode a command received by the processor and control an operation for information based on a result of decoding the command; an auxiliary memory device configured to store a program for decoding the command and the information; a main memory device configured to call and store the program and the information from the auxiliary memory device such that the processor can perform the operation using the program and the information when executing the program; and an interface device configured to perform communication between at least one of the processor, the auxiliary memory device and the main memory device and the outside, wherein the semiconductor memory is part of the auxiliary memory device or the main memory device in the processing system.

The electronic device may further include a data storage system which includes: a storage device configured to store data and conserve stored data regardless of power supply; a controller configured to control input and output of data to and from the storage device according to a command inputted form an outside; a temporary storage device configured to temporarily store data exchanged between the storage device and the outside; and an interface configured to perform communication between at least one of the storage device, the controller and the temporary storage device and the outside, wherein the semiconductor memory is part of the storage device or the temporary storage device in the data storage system.

The electronic device may further include a memory system which includes: a memory configured to store data and conserve stored data regardless of power supply; a memory controller configured to control input and output of data to and from the memory according to a command inputted form an outside; a buffer memory configured to buffer data exchanged between the memory and the outside; and an interface configured to perform communication between at least one of the memory, the memory controller and the buffer memory and the outside, wherein the semiconductor memory is part of the memory or the buffer memory in the memory system.

These and other aspects, implementations and associated advantages are described in greater detail in the drawings, the description and the claims.

### BRIEF DESCRIPTION OF THE DRAWINGS

FIG. 1 is a cross sectional view illustrating a variable resistance element in accordance with an implementation of the present disclosure.

FIG. 2 is a graph showing a perpendicular magnetic anisotropy characteristic of a first magnetic layer of a variable resistance element.

FIG. 3 is a graph showing a damping constant characteristic of a first magnetic layer of a variable resistance element.

FIG. 4 is a cross sectional view illustrating an example of a semiconductor device including the variable resistance element of FIG. 1.

FIG. 5 is a cross sectional view illustrating another example of a semiconductor device including the variable resistance element of FIG. 1.

FIG. 6 is a cross sectional view illustrating another example of a semiconductor device including the variable resistance element of FIG. 1.

FIG. 7 is a cross sectional view illustrating another example of a semiconductor device including the variable resistance element of FIG. 1.

FIG. 8 is an example of configuration diagram of a microprocessor implementing memory circuitry based on the disclosed technology.

FIG. 9 is an example of configuration diagram of a processor implementing memory circuitry based on the disclosed technology.

FIG. 10 is an example of configuration diagram of a system implementing memory circuitry based on the disclosed technology.

FIG. 11 is an example of configuration diagram of a data storage system implementing memory circuitry based on the disclosed technology.

FIG. 12 is an example of configuration diagram of a memory system implementing memory circuitry based on the disclosed technology.

### DETAILED DESCRIPTION

Various examples and implementations of the disclosed technology are described below in detail with reference to the accompanying drawings.

The drawings may not be necessarily to scale and in some instances, proportions of at least some of structures in the drawings may have been exaggerated in order to clearly illustrate certain features of the described examples or implementations. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure may not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

A semiconductor device in accordance with implementations of the present disclosure may include one or more variable resistance elements. Each of the variable resistance elements may be switched between different resistant states according to an applied voltage or current to store different data. That is, each of the variable resistance elements may serve as a memory cell.

Specifically, the variable resistance element may include an MTJ (Magnetic Tunnel Junction) structure which includes a first magnetic layer having a variable magnetization direction, a second magnetic layer having a pinned magnetization direction, and a tunnel barrier layer interposed between the first magnetic layer and the second magnetic layer. The first magnetic layer may store data according to the magnetization direction thereof, and be referred to as a free layer, a storage layer, etc. The second magnetic layer may have the pinned magnetization direction to be compared with the magnetization direction of the first magnetic layer, and be referred to as a pinned layer, a reference layer, etc. According to a voltage or current applied to the variable resistance element, the magnetization direction of the first magnetic layer may be changed so that the magnetization directions of the first and second magnetic layers become parallel or anti-parallel to each other. Therefore, the variable resistance element may be switched between a low resistant state and a high resistant state. The magnetization direction of the first magnetic layer may be changed by a spin transfer torque. Also, the magnetization directions of the first and second magnetic layers may be perpendicular to surfaces of the first and the second magnetic layers 120, 140, respectively, or be parallel to the surfaces of the first and the second magnetic layers 120, 140, respectively.

The first magnetic layer and the second magnetic layer may have damping constant (a). Since current density required for the above spin transfer torque is proportional to this damping constant, it is desirable for the damping constant of the first magnetic layer serving as the free layer to be low. That is, when the damping constant of the first magnetic layer is low, the magnetization direction of the first magnetic layer may be changed by a small amount current. As a result, switching characteristics of the variable resistance element may be improved.

However, when the magnetization directions of the first and second magnetic layers are perpendicular to the surfaces of the first and the second magnetic layers 120, 140, respectively, it is difficult to decrease the damping constant of the first and second magnetic layers while obtaining perpendicular magnetic anisotropy of the first and second magnetic layers at the same time. This is because magnetic materials having a strong perpendicular magnetic anisotropy are known for having large damping constants.

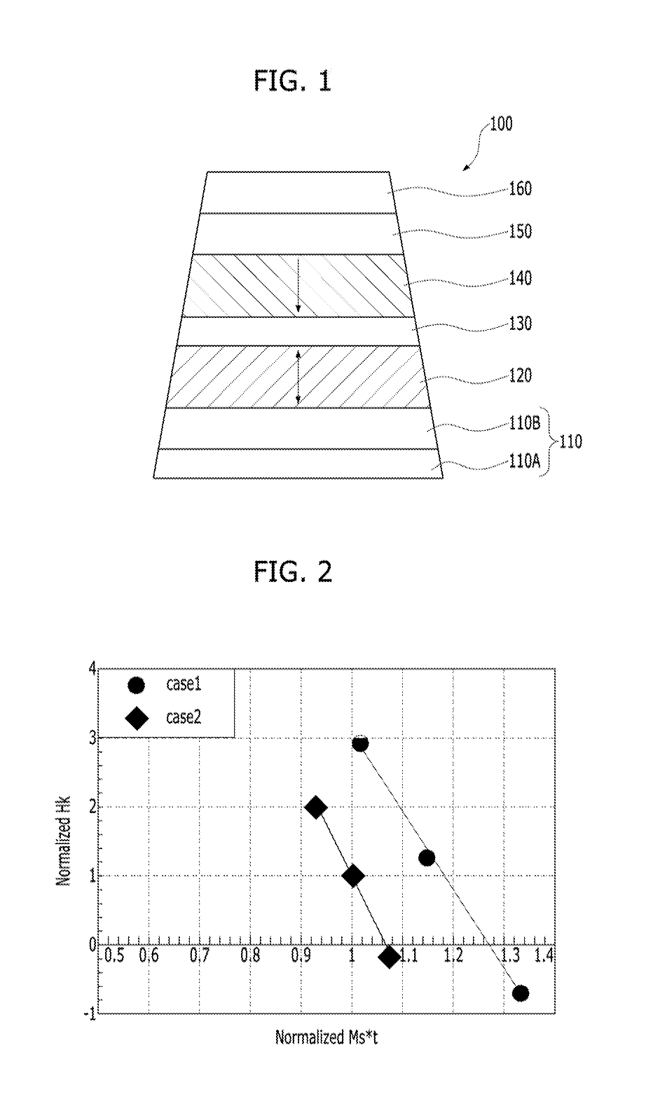

According to an implementation, it is possible to decrease a damping constant of a magnetic layer while obtaining perpendicular magnetic anisotropy of the magnetic layer. This will be described in more detail with reference to FIGS. 1 to 3.

FIG. 1 is a cross sectional view illustrating a variable resistance element in accordance with an implementation of the present disclosure.

Referring to FIG. 1, the variable resistance element 100 may include an MTJ structure which includes a first magnetic layer 120 having a variable magnetization direction, a second magnetic layer 140 having a pinned magnetization direction, and a tunnel barrier layer 130 interposed between the first magnetic layer 120 and the second magnetic layer 140.

The first magnetic layer 120 and the second magnetic layer 140 may include a ferromagnetic material such as an alloy in which the main component is Fe, Ni and/or Co. For example, the first magnetic layer 120 and the second magnetic layer 140 may include an Fe—Pt alloy, an Fe—Pd alloy, a Co—Pd alloy, a Co—Pt alloy, an Fe—Ni—Pt alloy, a Co—Fe—Pt alloy, a Co—Ni—Pt alloy, etc. Magnetization directions of the first magnetic layer 120 and the second magnetic layer 140 may be perpendicular to surfaces of the first and the second magnetic layers 120, 140, respectively. For example, as shown by arrows, the magnetization direction of the first magnetic layer 120 may be changed between a direction from top to bottom and a direction from bottom to top, and the magnetization direction of the second magnetic layer 140 may be fixed in a direction from top to bottom.

The tunnel barrier layer 130 may change the magnetization direction of the first magnetic layer 120 by tunneling of electrons. The tunnel barrier layer 130 may include an insulating oxide such as MgO, CaO, SrO, TiO, VO, NbO, etc.

The variable resistance element 100 may further include one or more additional layers (see reference numerals 110, 150 and 160) performing various functions in order to improve characteristics of the MTJ structure or facilitate fabrication processes. For example, the variable resistance element 100 may further include an under layer 110 which is located under the MTJ structure, a magnetic correction layer 150 which is located over the MTJ structure, and/or a capping layer 160 which is an uppermost part of the variable resistance element 110.

Specially, in this implementation, the under layer 110 may include a first metal nitride layer 110A and a second metal nitride layer 110B.

The first metal nitride layer 110A may have a NaCl crystal structure to improve crystal orientation of the second metal nitride layer 110B located over the first metal nitride layer 110A. The first metal nitride layer 110A may include a hafnium nitride, a zirconium nitride, a titanium nitride, etc.

The second metal nitride layer 110B may include a light metal to reduce the damping constant of the first magnetic layer 120 located over the second metal nitride layer 110B. The light metal may include titanium or a metal, such as an aluminum, which has a lower specific gravity than the titanium. The second metal nitride layer 110B may include a metal of atomic weight less than Ti to reduce the damping constant of the first magnetic layer 120. The second metal nitride layer 110B may include a period 2 element metal, a period 3 element metal, or a period 4 element metal to reduce the damping constant of the first magnetic layer 120. Furthermore, since the crystal orientation of the second metal nitride layer 110B is improved by the first metal nitride layer 110A, the second metal nitride layer 110B may improve crystal orientation of the first magnetic layer 120 located over the second metal nitride layer 110B. The second metal nitride layer 110B may have a ZnO crystal structure, and the first magnetic layer 120 may have an Fe-BCC crystal structure or an amorphous structure.

The first and second metal nitride layers 110A and 110B may be conductive. This is because the under layer 110 is coupled to a contact plug (not shown) located under the under layer 110 and transfers a current or voltage supplied through the contact plug to the MTJ structure.

According to the embodiment employing the first and second metal nitride layers 110A and 110B as the under layer 110, one or more of the following advantages may be achieved.

First, since crystal orientation characteristics of the second metal nitride layer 110B is improved by the first metal nitride layer 110A, it is possible to increase a perpendicular magnetic anisotropy of the first magnetic layer 120 located over the second metal nitride layer 110B. This advantage is shown in FIG. 2.

FIG. 2 is a graph showing perpendicular magnetic anisotropy characteristics of a first magnetic layer of a variable resistance element. In FIG. 2, the horizontal axis represents the value of a normalized Ms (saturation magnetization)*t (thickness), and the vertical axis represents the value of a normalized Hk (perpendicular anisotropy field). Case1 of FIG. 2 is obtained from a structure where a double-layered structure is located under the first magnetic layer, as shown in FIG. 1. In case1, the double-layered structure may be a stack of a HfN layer and an AlN layer. The case2 of FIG. 2 is obtained from a conventional structure where a single metal layer is located under the first magnetic layer.

Referring to FIG. 2, an Hk value of the first magnetic layer in case1 is larger than that in case 2. That is, in case1, the perpendicular magnetic anisotropy of the first magnetic layer may be further improved.

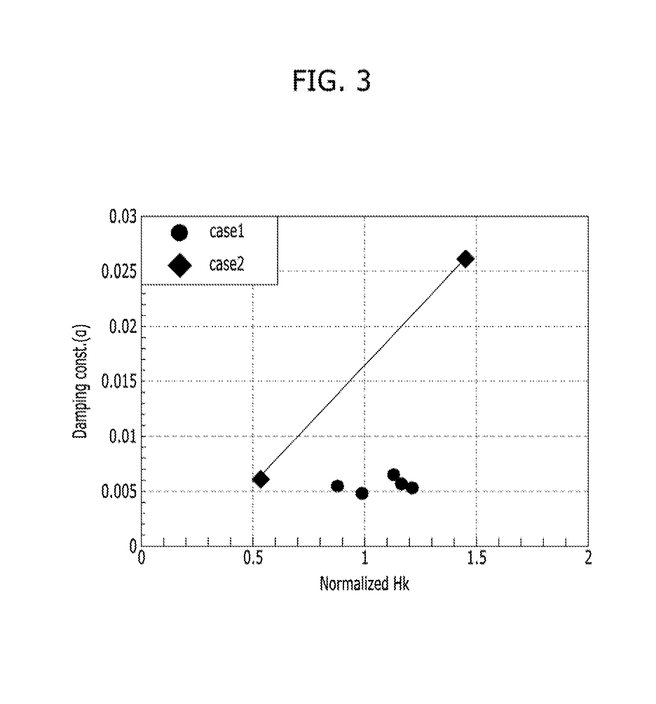

Next, since the second metal nitride layer 110B includes a light metal, the damping constant of the first magnetic layer 120 located over the second metal nitride layer 110B may be reduced. This advantage can be confirmed from FIG. 3.

FIG. 3 is a graph showing a damping constant characteristic of a first magnetic layer of a variable resistance element according to an embodiment. In FIG. 3, the horizontal axis represents the value of a normalized Hk, and the vertical axis represents the value of a damping constant. Case1 of FIG. 3 is obtained from a structure where a double-layered structure is located under the first magnetic layer, as shown in FIG. 1. Specially, in case1, the double-layered structure may be a stack of a HfN layer and an AlN layer. Case2 of FIG. 3 is obtained from a conventional structure where a single metal layer is located under the first magnetic layer.

Referring to FIG. 3, case1 shows a low damping constant value, less than 0.01, regardless of the Hk value.

That is, as shown in case1 and case2, it is possible to decrease the damping constant of the first magnetic layer 120 while obtaining desirable perpendicular magnetic anisotropy characteristics in the first magnetic layer 120 by employing the first metal nitride layer 110A having the NaCl crystal structure and the second metal nitride layer 110B containing the light metal as the under layer 110, which is located under the first magnetic layer 120. As a result, switching characteristics of the variable resistance element 100 may improve.

Referring back to FIG. 1, the magnetic correction layer 150 may offset the influence of a stray field generated by the second magnetic layer 140. The magnetic correction layer 150 may include a ferromagnetic material which has a magnetization direction opposite to the second magnetic layer 140 or an anti-ferromagnetic material. In this case, since the stray field influence by the second magnetic layer 140 on the first magnetic layer 120 is reduced, a bias magnetic field applied to the first magnetic layer 120 may be reduced. In this implementation, the magnetic correction layer 150 is located over the MTJ structure. However, the position of the magnetic correction layer 150 may be changed in various ways. For example, the magnetic correction layer 150 may be located under the under layer 110.

The capping layer 160 may serve as a hard mask in a patterning process for forming the variable resistance element 100. The capping layer 160 may include a conductive material such as a metal, etc. Specifically, the capping layer 160 may be formed using a metal-based material which has a small pin-hole and a high resistance by a dry or wet etching process. For example, the capping layer 160 may be formed of a noble metal such as Ru, etc.

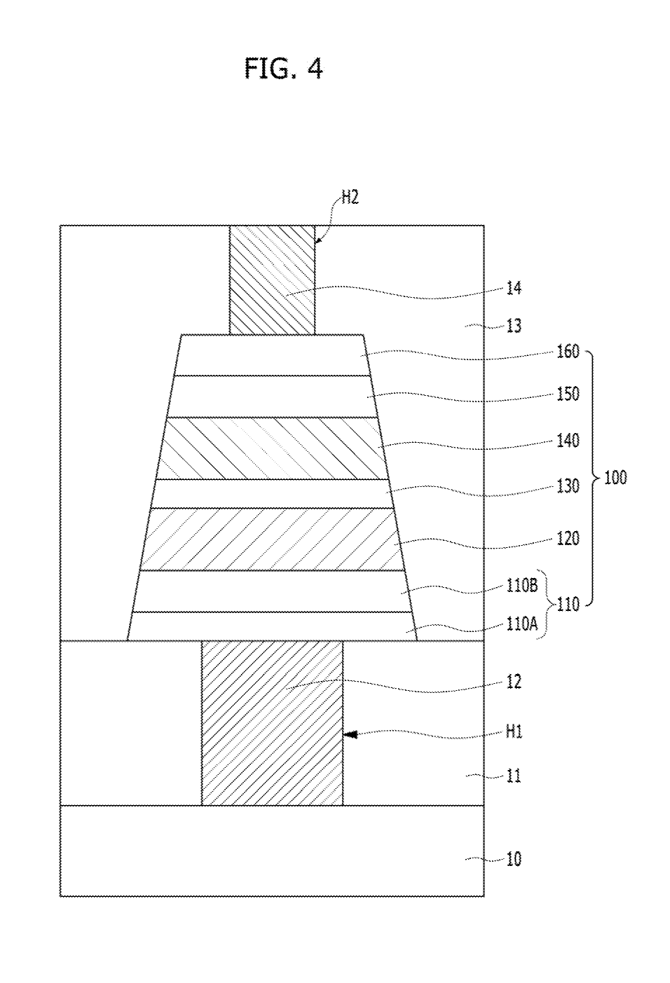

FIG. 4 is a cross sectional view illustrating an example of a semiconductor device including the variable resistance element 100 of FIG. 1.

Referring to FIG. 4, the semiconductor device may include a substrate 10 and a first interlayer dielectric layer 11. A bottom contact 12 is formed over the substrate 10 and penetrates through the first interlayer dielectric layer 11 to be coupled to a part of the substrate 10. The variable resistance element 100 is formed over the first interlayer dielectric layer 11 and has a bottom end coupled to the bottom contact 12. A top contact 14 is formed over the variable resistance element 100 and penetrates through a second interlayer dielectric layer 13 to be coupled to a top end of the variable resistance element 100.

A method for fabricating the semiconductor device of FIG. 4 is briefly described below.

First, the substrate 10 may be provided. The substrate 10 may include underlying elements (not shown), for example, a switching element which is turned on or turned off to control supply of a voltage or current to the variable resistance element 100.

Then, the first interlayer dielectric layer 11 may be formed by depositing an insulating material such as a silicon oxide over the substrate 10, and a first hole H1 exposing a part of the substrate 10 may be formed by selectively etching the first interlayer dielectric layer 11. Then, the bottom contact 12 which is filled in the first hole H1 and has a top surface located at the same level as a top surface of the first interlayer dielectric layer 11 may be formed by depositing a conductive material filling the first hole H1 and performing a planarization process, for example, a CMP (Chemical Mechanical Polishing) process until the top surface of the first interlayer dielectric layer 11 is exposed. The bottom contact 12 may be coupled to the switching element of the substrate 10.

Then, the variable resistance element 100, which has an island shape when viewed from the top and has a bottom end coupled to the bottom contact 12, may be formed by sequentially forming the under layer 110 including the first metal nitride layer 110A and the second metal nitride layer 110B, the first magnetic layer 120, the tunnel barrier layer 130, the second magnetic layer 140, the magnetic correction layer 150, and the capping layer 160 over the first interlayer dielectric layer 11 and the bottom contact 12, and selectively etching the layers 110, 120, 130, 140, 150 and 160.

Then, a second interlayer dielectric layer 13 covering the variable resistance element 100 may be formed, and then, a second hole H2 exposing the top surface of the variable resistance element 100 may be formed by selectively etching the second interlayer dielectric layer 13. Then, the top contact 14 may be formed by filling the second hole H2 with a conductive material.

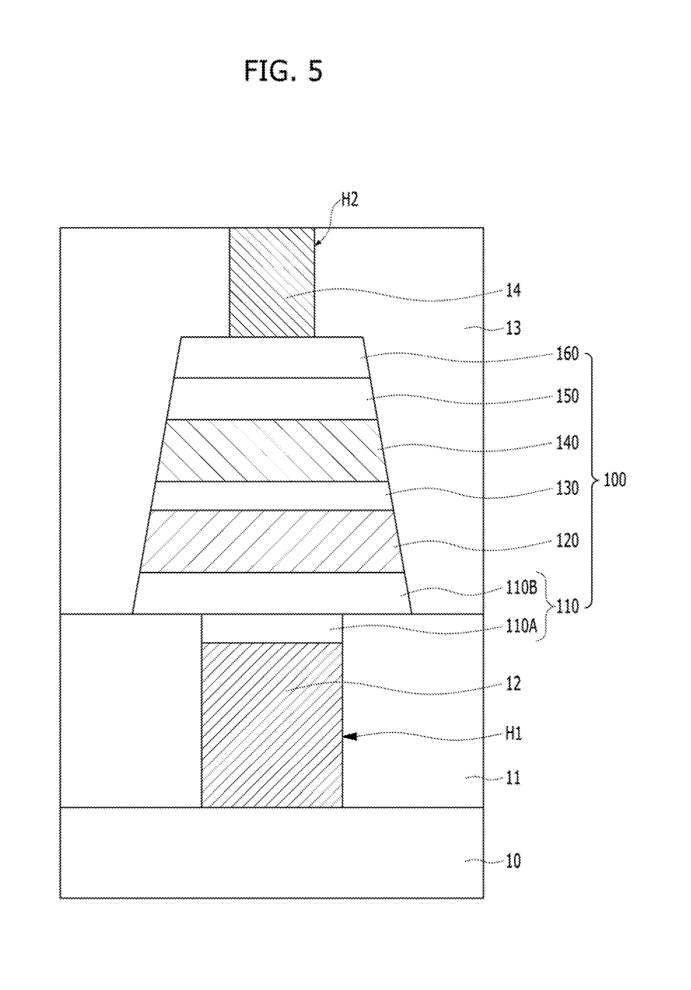

By this implementation, all the layers constituting the variable resistance element 100 may be located over the first interlayer dielectric layer 11 and have sidewalls aligned with each other. However, in other implementations, the under layer 110 may be modified so that a part or all of the under layer 110 is buried in the first interlayer dielectric layer 11. In this case, the etching process for forming the variable resistance element 100 may be simplified. Such modification can be shown in FIGS. 5 to 7.

FIG. 5 is a cross sectional view illustrating another example of a semiconductor device including the variable resistance element of FIG. 1. Differences from the implementation of FIG. 4 are described below.

Referring to FIG. 5, the bottom contact 12 may fill a part of the first hole H1 formed in the first interlayer dielectric layer 11, and the first metal nitride layer 110A located at a lowermost part of the variable resistance element 100 may be formed over the bottom contact 12 and fill a remaining space of the first hole H1 in which the bottom contact 12 is formed. That is, a stacked structure of the bottom contact 12 and the first metal nitride layer 110A may fill in the first hole H1. Therefore, remaining layers of the variable resistance element 100, that is, the second metal nitride layer 110B, the first magnetic layer 120, the tunnel barrier layer 130, the second magnetic layer 140, the magnetic correction layer 150, and the capping layer 160 may be formed over the first interlayer dielectric layer 11.

A method for fabricating the semiconductor device of FIG. 5 is briefly described below. First, the first interlayer dielectric layer 11 having the first hole H1 may be formed. Then, the bottom contact 12 filling a lower part of the first hole H1 may be formed by depositing a conductive material to fill the first hole H1 and performing an etch back process until a top surface of the conductive layer is lower than the top surface of the first interlayer dielectric layer 11. Then, the first metal nitride layer 110A may be formed by forming a metal nitride to a thickness sufficient for filling the remaining space of the first hole H1 and performing a planarization process until the top surface of the first interlayer dielectric layer 11 is exposed. Then, the remaining layers of the variable resistance element 100 may be formed by sequentially forming the second metal nitride layer 110B, the first magnetic layer 120, the tunnel barrier layer 130, the second magnetic layer 140, the magnetic correction layer 150, and the capping layer 160 over the first interlayer dielectric layer 11 and the first metal nitride layer 110A, and selectively etching the layers 110B, 120, 130, 140, 150 and 160.

By this implementation, the first metal nitride layer 110A which constitutes a lowermost part of the variable resistance element 100 may be buried in the first metal nitride layer 11 and have a sidewall that is aligned with a sidewall of the bottom contact 12. The remaining layers of the variable resistance element 100 may be located over the first interlayer dielectric layer 110A and have sidewalls aligned with each other.

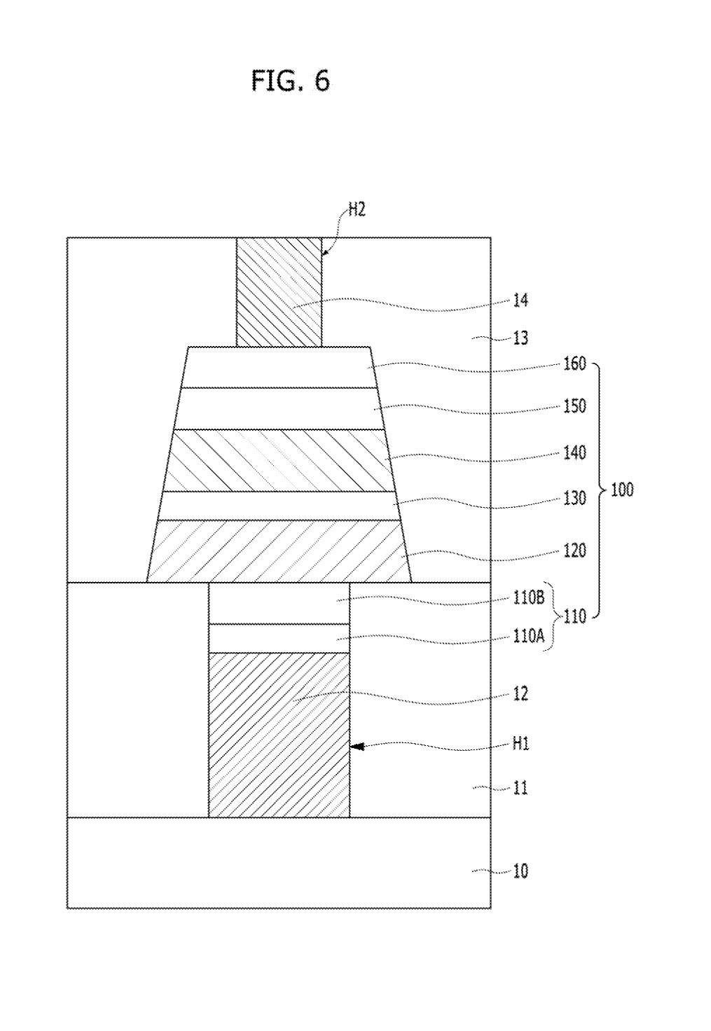

FIG. 6 is a cross sectional view illustrating another example of a semiconductor device including the variable resistance element of FIG. 1. Differences from the implementation of FIG. 4 are described below.

Referring to FIG. 6, the bottom contact 12 may fill a part of the first hole H1 formed in the first interlayer dielectric layer 11, and the under layer 110 of the variable resistance element 100 may be formed over the bottom contact 12 and fill a remaining space of the first hole H1 in which the bottom contact 12 is formed. That is, a stack structure in which the bottom contact 12, the first metal nitride layer 110A, and the second metal nitride layer 110B are sequentially stacked, may fill in the first hole H1. Therefore, remaining layers of the variable resistance element 100, that is, the first magnetic layer 120, the tunnel barrier layer 130, the second magnetic layer 140, the magnetic correction layer 150, and the capping layer 160 may be formed over the first interlayer dielectric layer 11.

A method for fabricating the semiconductor device of FIG. 6 is briefly described below. First, the first interlayer dielectric layer 11 having the first hole H1 may be formed. The bottom contact 12 filling a lower part of the first hole H1 may be formed. Then, the first metal nitride layer 110A partially filling the remaining space of the first hole H1 may be formed by depositing a first metal nitride over a resultant structure in which the bottom contact 12 is formed and performing an etch back process until a top surface of the first metal nitride is lower than the top surface of the first interlayer dielectric layer 11. Then, the second metal nitride layer 110B filling the rest of the remaining space of the first hole H1 may be formed by forming a second metal nitride to a thickness sufficient for filling the rest of the remaining space of the first hole H1 and performing a planarization process until the top surface of the first interlayer dielectric layer 11 is exposed. Then, the remaining layers of the variable resistance element 100 may be formed by sequentially forming the first magnetic layer 120, the tunnel barrier layer 130, the second magnetic layer 140, the magnetic correction layer 150, and the capping layer 160 over the first interlayer dielectric layer 11 and the second metal nitride layer 110B, and selectively etching the layers 120, 130, 140, 150 and 160.

Under this implementation, the entire under layer 110 may be buried in the first metal nitride layer 11 and a sidewall of the under layer 110 is aligned with a sidewall of the bottom contact 12. The remaining layers of the variable resistance element 100 may be located over the first interlayer dielectric layer 11 and sidewalls of the remaining layers of the variable resistance element 100 are aligned with each other.

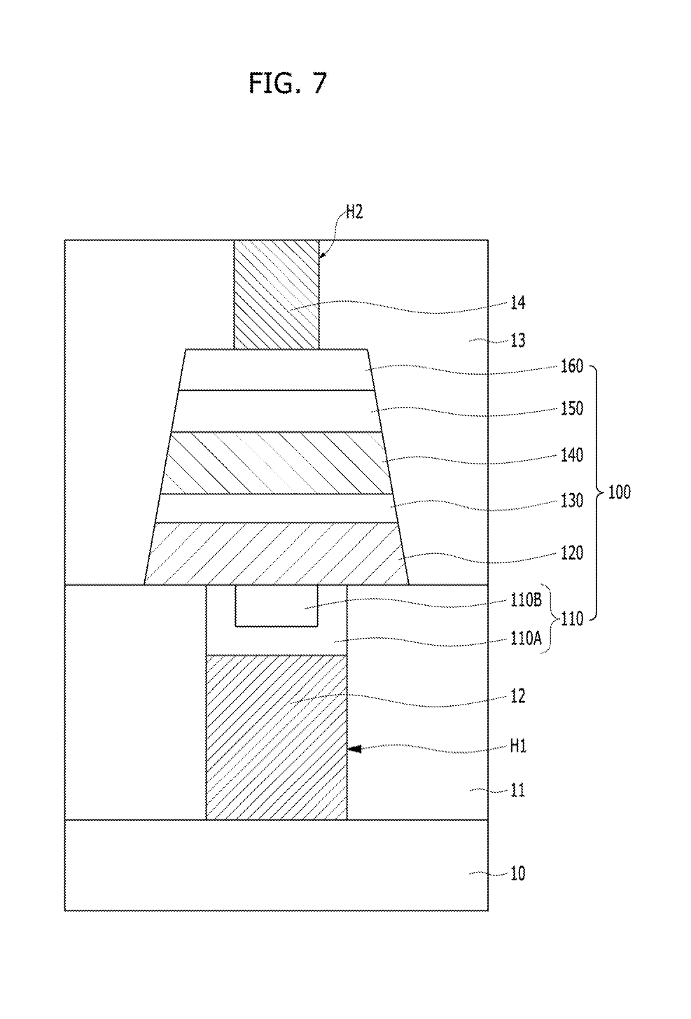

FIG. 7 is a cross sectional view illustrating another example of a semiconductor device including the variable resistance element of FIG. 1. Differences from the implementation of FIG. 6 are described below.

Referring to FIG. 7, the bottom contact 12 may fill a part of the first hole H1 formed in the first interlayer dielectric layer 11, and the under layer 110 of the variable resistance element 100 may be formed over the bottom contact 12 and fill a remaining space of the first hole H1 in which the bottom contact 12 is formed. Shapes of the first and second metal nitride layers 110A and 110B may be different from those in FIG. 6. The first metal nitride layer 110A may be formed along a sidewall and a bottom surface of the remaining space of the first hole H1 in a liner pattern, leaving an empty space in a center of the first metal nitride layer 110A. The second metal nitride layer 110B may fill the empty space formed in the center of the first metal nitride layer 110A so that a sidewall and a bottom surface of the second metal nitride layer 110B are surrounded by the first metal nitride layer 110A. Top surfaces of the first and second metal nitride layers 110A and 110B are located at the same level as the top surface of the first interlayer dielectric layer 11.

The first and second metal nitride layers 110A and 110B may be formed by sequentially forming the first metal nitride and the second metal nitride over the resultant structure in which the bottom contact 12 is formed and performing a planarization process until the top surface of the first interlayer dielectric layer 11 is exposed.

Under this implementation, the entire under layer 110 may be buried in the first metal nitride layer 11 and a sidewall of the first metal nitride layer 110A may be aligned with a sidewall of the bottom contact 12. The remaining layers of the variable resistance element 100 may be located over the first interlayer dielectric layer 11 and sidewalls of the remaining layers of the variable resistance element 100 may be aligned with each other.

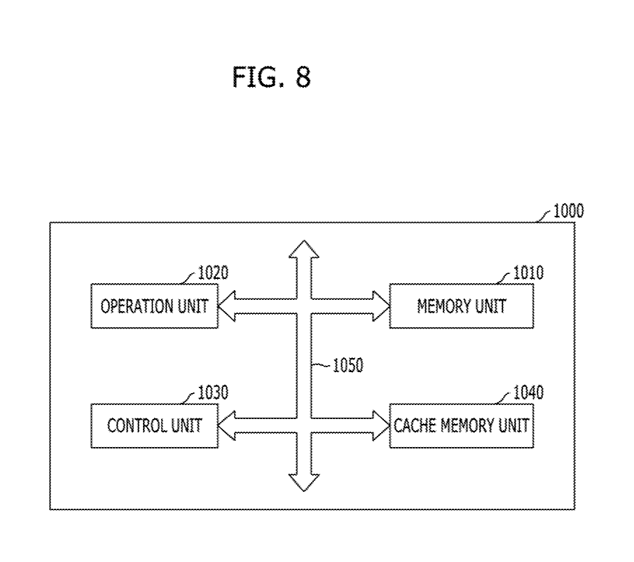

The above and other memory circuits or semiconductor devices based on the disclosed technology can be used in a wide range of devices or systems. FIGS. 8-12 provide some examples of devices or systems employing the memory circuits disclosed herein.

FIG. 8 is an example of configuration diagram of a microprocessor implementing memory circuitry based on the disclosed technology.

Referring to FIG. 8, a microprocessor 1000 may perform tasks for controlling and tuning a series of processes of receiving data from various external devices, processing the data, and outputting processing results to external devices. The microprocessor 1000 may include a memory unit 1010, an operation unit 1020, a control unit 1030, and so on. The microprocessor 1000 may be various data processing units such as a central processing unit (CPU), a graphic processing unit (GPU), a digital signal processor (DSP) and an application processor (AP).

The memory unit 1010 is a part which stores data in the microprocessor 1000, as a processor register, register or the like. The memory unit 1010 may include a data register, an address register, a floating point register and so on. Besides, the memory unit 1010 may include various registers. The memory unit 1010 may perform the function of temporarily storing data for which operations are to be performed by the operation unit 1020, result data of performing the operations, and addresses where data for performing of the operations are stored.

The memory unit 1010 may include one or more of the above-described semiconductor devices in accordance with the implementations. For example, the memory unit 1010 may include an under layer; a first magnetic layer located over the under layer and having a variable magnetization direction; a tunnel barrier layer located over the first magnetic layer; and a second magnetic layer located over the tunnel barrier layer and having a pinned magnetization direction, wherein the under layer includes a first metal nitride layer having a NaCl crystal structure and a second metal nitride layer containing a light metal. Through this, data storage characteristics of the memory unit 1010 may be improved. As a consequence, operating characteristics of the microprocessor 1000 may be improved.

The operation unit 1020 may perform four arithmetical operations or logical operations according to results that the control unit 1030 decodes commands. The operation unit 1020 may include at least one arithmetic logic unit (ALU) and so on.

The control unit 1030 may receive signals from the memory unit 1010, the operation unit 1020 and an external device of the microprocessor 1000, perform extraction, decoding of commands, and controlling input and output of signals of the microprocessor 1000, and execute processing represented by programs.

The microprocessor 1000 according to the present implementation may additionally include a cache memory unit 1040 which can temporarily store data to be inputted from an external device other than the memory unit 1010 or to be outputted to an external device. In this case, the cache memory unit 1040 may exchange data with the memory unit 1010, the operation unit 1020 and the control unit 1030 through a bus interface 1050.

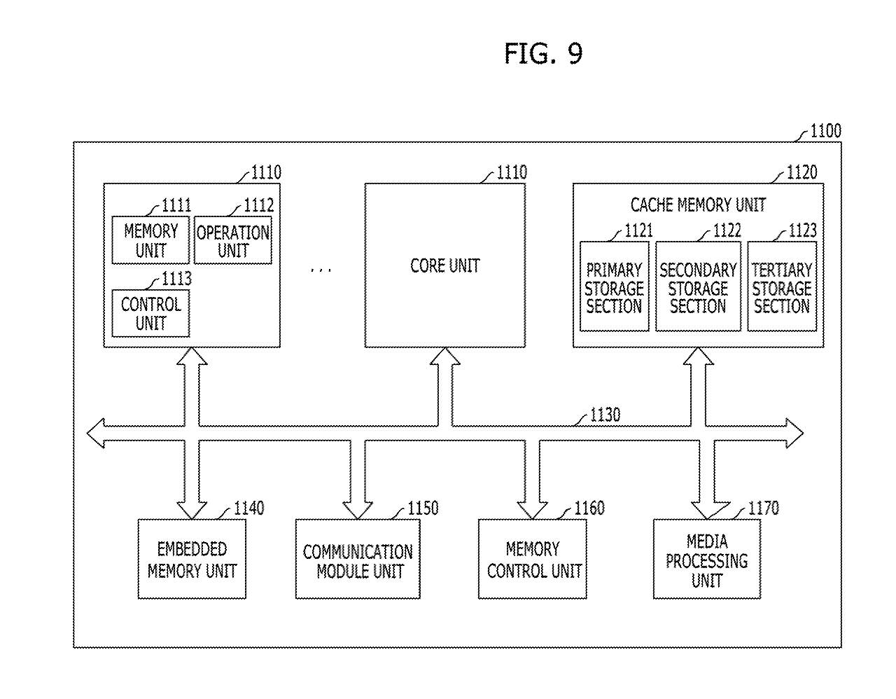

FIG. 9 is an example of configuration diagram of a processor implementing memory circuitry based on the disclosed technology.

Referring to FIG. 9, a processor 1100 may improve performance and realize multi-functionality by including various functions other than those of a microprocessor which performs tasks for controlling and tuning a series of processes of receiving data from various external devices, processing the data, and outputting processing results to external devices. The processor 1100 may include a core unit 1110 which serves as the microprocessor, a cache memory unit 1120 which serves to storing data temporarily, and a bus interface 1130 for transferring data between internal and external devices. The processor 1100 may include various system-on-chips (SoCs) such as a multi-core processor, a graphic processing unit (GPU) and an application processor (AP).

The core unit 1110 of the present implementation is a part which performs arithmetic logic operations for data inputted from an external device, and may include a memory unit 1111, an operation unit 1112 and a control unit 1113.

The memory unit 1111 is a part which stores data in the processor 1100, as a processor register, a register or the like. The memory unit 1111 may include a data register, an address register, a floating point register and so on. Besides, the memory unit 1111 may include various registers. The memory unit 1111 may perform the function of temporarily storing data for which operations are to be performed by the operation unit 1112, result data of performing the operations and addresses where data for performing of the operations are stored. The operation unit 1112 is a part which performs operations in the processor 1100. The operation unit 1112 may perform four arithmetical operations, logical operations, or the like according to decoded commands outputted from the control unit 1113. The operation unit 1112 may include at least one arithmetic logic unit (ALU) and so on. The control unit 1113 may receive signals from the memory unit 1111, the operation unit 1112 and an external device of the processor 1100, perform extraction, decoding of commands, controlling input and output of signals of processor 1100, and execute processing represented by programs.

The cache memory unit 1120 is a part which temporarily stores data to compensate for a difference in data processing speed between the core unit 1110 operating at a high speed and an external device operating at a low speed. The cache memory unit 1120 may include a primary storage section 1121, a secondary storage section 1122 and a tertiary storage section 1123. In general, the cache memory unit 1120 includes the primary and secondary storage sections 1121 and 1122, and may include the tertiary storage section 1123 in the case where high storage capacity is required. As the occasion demands, the cache memory unit 1120 may include an increased number of storage sections. That is to say, the number of storage sections which are included in the cache memory unit 1120 may be changed according to a design. The speeds at which the primary, secondary and tertiary storage sections 1121, 1122 and 1123 store and discriminate data may be the same or different. In the case where the speeds of the respective storage sections 1121, 1122 and 1123 are different, the speed of the primary storage section 1121 may be largest. At least one storage section of the primary storage section 1121, the secondary storage section 1122 and the tertiary storage section 1123 of the cache memory unit 1120 may include one or more of the above-described semiconductor devices in accordance with the implementations. For example, the cache memory unit 1120 may include an under layer; a first magnetic layer located over the under layer and having a variable magnetization direction; a tunnel barrier layer located over the first magnetic layer; and a second magnetic layer located over the tunnel barrier layer and having a pinned magnetization direction, wherein the under layer includes a first metal nitride layer having a NaCl crystal structure and a second metal nitride layer containing a light metal. Through this, data storage characteristics of the cache memory unit 1120 may be improved. As a consequence, operating characteristics of the processor 1100 may be improved.

Although it was shown in FIG. 9 that all the primary, secondary and tertiary storage sections 1121, 1122 and 1123 are configured inside the cache memory unit 1120, it is to be noted that all the primary, secondary and tertiary storage sections 1121, 1122 and 1123 of the cache memory unit 1120 may be configured outside the core unit 1110 and may compensate for a difference in data processing speed between the core unit 1110 and the external device. Meanwhile, it is to be noted that the primary storage section 1121 of the cache memory unit 1120 may be disposed inside the core unit 1110 and the secondary storage section 1122 and the tertiary storage section 1123 may be configured outside the core unit 1110 to strengthen the function of compensating for a difference in data processing speed. In another implementation, the primary and secondary storage sections 1121, 1122 may be disposed inside the core units 1110 and tertiary storage sections 1123 may be disposed outside core units 1110.

The bus interface 1130 is a part which connects the core unit 1110, the cache memory unit 1120 and external device and allows data to be efficiently transmitted.

The processor 1100 according to the present implementation may include a plurality of core units 1110, and the plurality of core units 1110 may share the cache memory unit 1120. The plurality of core units 1110 and the cache memory unit 1120 may be directly connected or be connected through the bus interface 1130. The plurality of core units 1110 may be configured in the same way as the above-described configuration of the core unit 1110. In the case where the processor 1100 includes the plurality of core unit 1110, the primary storage section 1121 of the cache memory unit 1120 may be configured in each core unit 1110 in correspondence to the number of the plurality of core units 1110, and the secondary storage section 1122 and the tertiary storage section 1123 may be configured outside the plurality of core units 1110 in such a way as to be shared through the bus interface 1130. The processing speed of the primary storage section 1121 may be larger than the processing speeds of the secondary and tertiary storage section 1122 and 1123. In another implementation, the primary storage section 1121 and the secondary storage section 1122 may be configured in each core unit 1110 in correspondence to the number of the plurality of core units 1110, and the tertiary storage section 1123 may be configured outside the plurality of core units 1110 in such a way as to be shared through the bus interface 1130.

The processor 1100 according to the present implementation may further include an embedded memory unit 1140 which stores data, a communication module unit 1150 which can transmit and receive data to and from an external device in a wired or wireless manner, a memory control unit 1160 which drives an external memory device, and a media processing unit 1170 which processes the data processed in the processor 1100 or the data inputted from an external input device and outputs the processed data to an external interface device and so on. Besides, the processor 1100 may include a plurality of various modules and devices. In this case, the plurality of modules which are added may exchange data with the core units 1110 and the cache memory unit 1120 and with one another, through the bus interface 1130.

The embedded memory unit 1140 may include not only a volatile memory but also a nonvolatile memory. The volatile memory may include a DRAM (dynamic random access memory), a mobile DRAM, an SRAM (static random access memory), and a memory with similar functions to above mentioned memories, and so on. The nonvolatile memory may include a ROM (read only memory), a NOR flash memory, a NAND flash memory, a phase change random access memory (PRAM), a resistive random access memory (RRAM), a spin transfer torque random access memory (STTRAM), a magnetic random access memory (MRAM), a memory with similar functions.

The communication module unit 1150 may include a module capable of being connected with a wired network, a module capable of being connected with a wireless network and both of them. The wired network module may include a local area network (LAN), a universal serial bus (USB), an Ethernet, power line communication (PLC) such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB) such as various devices which send and receive data without transmit lines, and so on.

The memory control unit 1160 is to administrate and process data transmitted between the processor 1100 and an external storage device operating according to a different communication standard. The memory control unit 1160 may include various memory controllers, for example, devices which may control IDE (Integrated Device Electronics), SATA (Serial Advanced Technology Attachment), SCSI (Small Computer System Interface), RAID (Redundant Array of Independent Disks), an SSD (solid state disk), eSATA (External SATA), PCMCIA (Personal Computer Memory Card International Association), a USB (universal serial bus), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The media processing unit 1170 may process the data processed in the processor 1100 or the data inputted in the forms of image, voice and others from the external input device and output the data to the external interface device. The media processing unit 1170 may include a graphic processing unit (GPU), a digital signal processor (DSP), a high definition audio device (HD audio), a high definition multimedia interface (HDMI) controller, and so on.

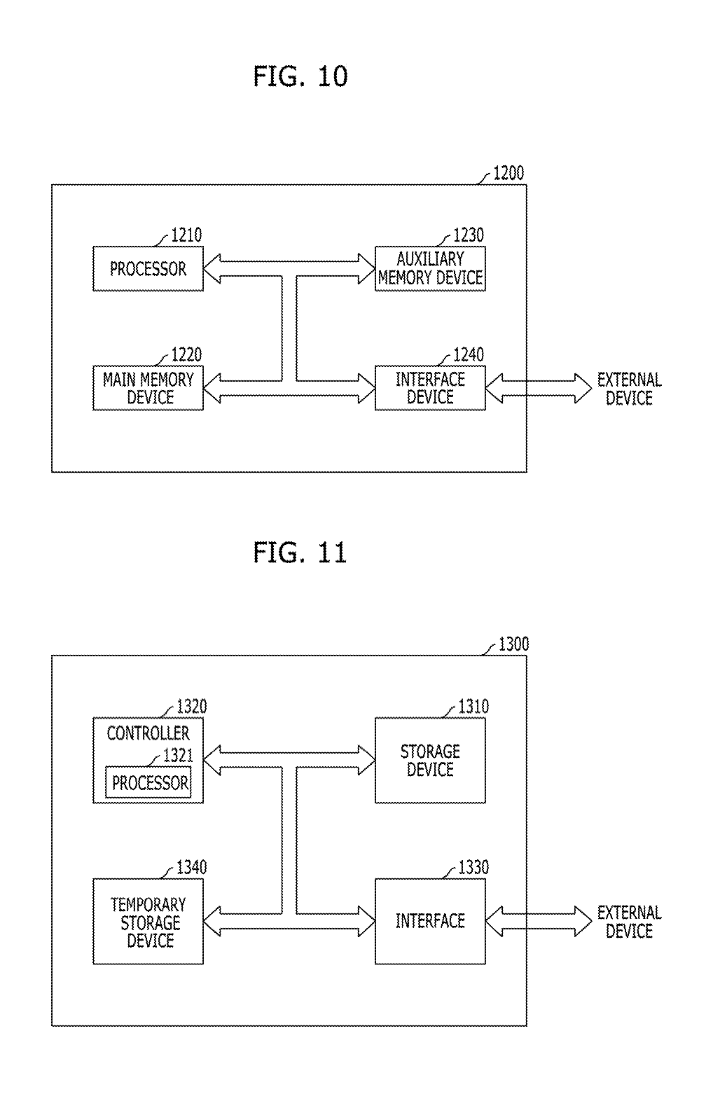

FIG. 10 is an example of configuration diagram of a system implementing memory circuitry based on the disclosed technology.

Referring to FIG. 10, a system 1200 as an apparatus for processing data may perform input, processing, output, communication, storage, etc. to conduct a series of manipulations for data. The system 1200 may include a processor 1210, a main memory device 1220, an auxiliary memory device 1230, an interface device 1240, and so on. The system 1200 of the present implementation may be various electronic systems which operate using processors, such as a computer, a server, a PDA (personal digital assistant), a portable computer, a web tablet, a wireless phone, a mobile phone, a smart phone, a digital music player, a PMP (portable multimedia player), a camera, a global positioning system (GPS), a video camera, a voice recorder, a telematics, an audio visual (AV) system, a smart television, and so on.

The processor 1210 may decode inputted commands and processes operation, comparison, etc. for the data stored in the system 1200, and controls these operations. The processor 1210 may include a microprocessor unit (MPU), a central processing unit (CPU), a single/multi-core processor, a graphic processing unit (GPU), an application processor (AP), a digital signal processor (DSP), and so on.

The main memory device 1220 is a storage which can temporarily store, call and execute program codes or data from the auxiliary memory device 1230 when programs are executed and can conserve memorized contents even when power supply is cut off. The main memory device 1220 may include one or more of the above-described semiconductor devices in accordance with the implementations. For example, the main memory device 1220 may include an under layer; a first magnetic layer located over the under layer and having a variable magnetization direction; a tunnel barrier layer located over the first magnetic layer; and a second magnetic layer located over the tunnel barrier layer and having a pinned magnetization direction, wherein the under layer includes a first metal nitride layer having a NaCl crystal structure and a second metal nitride layer containing a light metal. Through this, data storage characteristics of the main memory device 1220 may be improved. As a consequence, operating characteristics of the system 1200 may be improved.

Also, the main memory device 1220 may further include a static random access memory (SRAM), a dynamic random access memory (DRAM), and so on, of a volatile memory type in which all contents are erased when power supply is cut off. Unlike this, the main memory device 1220 may not include the semiconductor devices according to the implementations, but may include a static random access memory (SRAM), a dynamic random access memory (DRAM), and so on, of a volatile memory type in which all contents are erased when power supply is cut off.

The auxiliary memory device 1230 is a memory device for storing program codes or data. While the speed of the auxiliary memory device 1230 is slower than the main memory device 1220, the auxiliary memory device 1230 can store a larger amount of data. The auxiliary memory device 1230 may include one or more of the above-described semiconductor devices in accordance with the implementations. For example, the auxiliary memory device 1230 may include an under layer; a first magnetic layer located over the under layer and having a variable magnetization direction; a tunnel barrier layer located over the first magnetic layer; and a second magnetic layer located over the tunnel barrier layer and having a pinned magnetization direction, wherein the under layer includes a first metal nitride layer having a NaCl crystal structure and a second metal nitride layer containing a light metal. Through this, data storage characteristics of the auxiliary memory device 1230 may be improved. As a consequence, operating characteristics of the system 1200 may be improved.

Also, the auxiliary memory device 1230 may further include a data storage system (see the reference numeral 1300 of FIG. 11) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on. Unlike this, the auxiliary memory device 1230 may not include the semiconductor devices according to the implementations, but may include data storage systems (see the reference numeral 1300 of FIG. 11) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The interface device 1240 may be to perform exchange of commands and data between the system 1200 of the present implementation and an external device. The interface device 1240 may be a keypad, a keyboard, a mouse, a speaker, a mike, a display, various human interface devices (HIDs), a communication device, and so on. The communication device may include a module capable of being connected with a wired network, a module capable of being connected with a wireless network and both of them. The wired network module may include a local area network (LAN), a universal serial bus (USB), an Ethernet, power line communication (PLC), such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), such as various devices which send and receive data without transmit lines, and so on.

FIG. 11 is an example of configuration diagram of a data storage system implementing memory circuitry based on the disclosed technology.

Referring to FIG. 11, a data storage system 1300 may include a storage device 1310 which has a nonvolatile characteristic as a component for storing data, a controller 1320 which controls the storage device 1310, an interface 1330 for connection with an external device, and a temporary storage device 1340 for storing data temporarily. The data storage system 1300 may be a disk type such as a hard disk drive (HDD), a compact disc read only memory (CDROM), a digital versatile disc (DVD), a solid state disk (SSD), and so on, and a card type such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The storage device 1310 may include a nonvolatile memory which stores data semi-permanently. The nonvolatile memory may include a ROM (read only memory), a NOR flash memory, a NAND flash memory, a phase change random access memory (PRAM), a resistive random access memory (RRAM), a magnetic random access memory (MRAM), and so on.

The controller 1320 may control exchange of data between the storage device 1310 and the interface 1330. To this end, the controller 1320 may include a processor 1321 for performing an operation for, processing commands inputted through the interface 1330 from an outside of the data storage system 1300 and so on.

The interface 1330 is to perform exchange of commands and data between the data storage system 1300 and the external device. In the case where the data storage system 1300 is a card type, the interface 1330 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. In the case where the data storage system 1300 is a disk type, the interface 1330 may be compatible with interfaces, such as IDE (Integrated Device Electronics), SATA (Serial Advanced Technology Attachment), SCSI (Small Computer System Interface), eSATA (External SATA), PCMCIA (Personal Computer Memory Card International Association), a USB (universal serial bus), and so on, or be compatible with the interfaces which are similar to the above mentioned interfaces. The interface 1330 may be compatible with one or more interfaces having a different type from each other.

The temporary storage device 1340 can store data temporarily for efficiently transferring data between the interface 1330 and the storage device 1310 to achieve high performance of an interface with an external device, a controller and a system. The temporary storage device 1340 for temporarily storing data may include one or more of the above-described semiconductor devices in accordance with the implementations. The temporary storage device 1340 may include an under layer; a first magnetic layer located over the under layer and having a variable magnetization direction; a tunnel barrier layer located over the first magnetic layer; and a second magnetic layer located over the tunnel barrier layer and having a pinned magnetization direction, wherein the under layer includes a first metal nitride layer having a NaCl crystal structure and a second metal nitride layer containing a light metal. Through this, data storage characteristics of the storage device 1310 or the temporary storage device 1340 may be improved. As a consequence, operating characteristics and data storage characteristics of the data storage system 1300 may be improved.

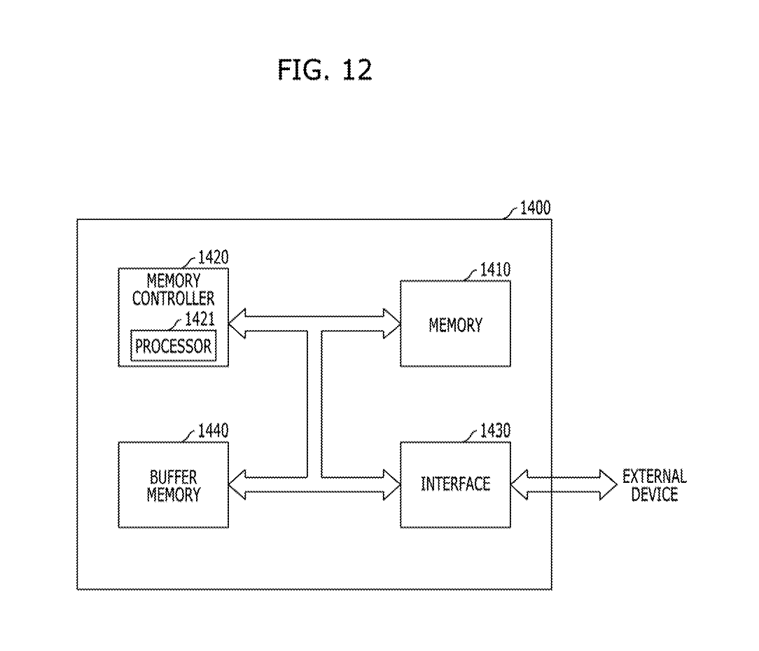

FIG. 12 is an example of configuration diagram of a memory system implementing memory circuitry based on the disclosed technology.

Referring to FIG. 12, a memory system 1400 may include a memory 1410 which has a nonvolatile characteristic as a component for storing data, a memory controller 1420 which controls the memory 1410, an interface 1430 for connection with an external device, and so on. The memory system 1400 may be a card type such as a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The memory 1410 for storing data may include one or more of the above-described semiconductor devices in accordance with the implementations. For example, the memory 1410 may include an under layer; a first magnetic layer located over the under layer and having a variable magnetization direction; a tunnel barrier layer located over the first magnetic layer; and a second magnetic layer located over the tunnel barrier layer and having a pinned magnetization direction, wherein the under layer includes a first metal nitride layer having a NaCl crystal structure and a second metal nitride layer containing a light metal. Through this, data storage characteristics of the memory 1410 may be improved. As a consequence, operating characteristics and data storage characteristics of the memory system 1400 may be improved.

Also, the memory 1410 according to the present implementation may further include a ROM (read only memory), a NOR flash memory, a NAND flash memory, a phase change random access memory (PRAM), a resistive random access memory (RRAM), a magnetic random access memory (MRAM), and so on, which have a nonvolatile characteristic.

The memory controller 1420 may control exchange of data between the memory 1410 and the interface 1430. To this end, the memory controller 1420 may include a processor 1421 for performing an operation for and processing commands inputted through the interface 1430 from an outside of the memory system 1400.

The interface 1430 is to perform exchange of commands and data between the memory system 1400 and the external device. The interface 1430 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. The interface 1430 may be compatible with one or more interfaces having a different type from each other.

The memory system 1400 according to the present implementation may further include a buffer memory 1440 for efficiently transferring data between the interface 1430 and the memory 1410 according to diversification and high performance of an interface with an external device, a memory controller and a memory system. For example, the buffer memory 1440 for temporarily storing data may include one or more of the above-described semiconductor devices in accordance with the implementations. The buffer memory 1440 may an under layer; a first magnetic layer located over the under layer and having a variable magnetization direction; a tunnel barrier layer located over the first magnetic layer; and a second magnetic layer located over the tunnel barrier layer and having a pinned magnetization direction, wherein the under layer includes a first metal nitride layer having a NaCl crystal structure and a second metal nitride layer containing a light metal. Through this, data storage characteristics of the buffer memory 1440 may be improved. As a consequence, operating characteristics and data storage characteristics of the memory system 1400 may be improved.

Moreover, the buffer memory 1440 according to the present implementation may further include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic. Unlike this, the buffer memory 1440 may not include the semiconductor devices according to the implementations, but may include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic.

As is apparent from the above descriptions, in the semiconductor device and the method for fabricating the same in accordance with the implementations, patterning of a resistance variable element is easy, and it is possible to secure the characteristics of the resistance variable element.

Features in the above examples of electronic devices or systems in FIGS. 8-12 based on the memory devices disclosed in this document may be implemented in various devices, systems or applications. Some examples include mobile phones or other portable communication devices, tablet computers, notebook or laptop computers, game machines, smart TV sets, TV set top boxes, multimedia servers, digital cameras with or without wireless communication functions, wrist watches or other wearable devices with wireless communication capabilities.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described. Other implementations, enhancements and variations can be made based on what is described and illustrated in this patent document.

What is claimed is:

1. An electronic device comprising semiconductor memory, wherein the semiconductor memory comprises:
an under layer;
a first magnetic layer located over the under layer and having a variable magnetization direction;
a tunnel barrier layer located over the first magnetic layer; and
a second magnetic layer located over the tunnel barrier layer and having a pinned magnetization direction; and
a bottom contact located under the under layer and coupled to the under layer,
wherein the under layer includes a first metal nitride layer having a NaCl crystal structure and a second metal nitride layer containing a light metal,
wherein the first metal nitride layer of the under layer has a sidewall aligned with a sidewall of the bottom contact,
wherein the first metal nitride layer has a liner shape and has an empty space inside the first metal nitride layer, and
wherein the second metal nitride layer fills the empty space.

2. An electronic device comprising semiconductor memory, wherein the semiconductor memory comprises:
an under layer;
a first magnetic layer located over the under layer and having a variable magnetization direction;
a tunnel barrier layer located over the first magnetic layer; and
a second magnetic layer located over the tunnel barrier layer and having a pinned magnetization direction; and
a microprocessor which includes:
a control unit configured to receive a signal including a command from an outside of the microprocessor, and perform extracting, decoding of the command, or controlling input or output of a signal of the microprocessor;
an operation unit configured to perform an operation based on a result that the control unit decodes the command; and
a memory unit configured to store data for performing the operation, data corresponding to a result of performing the operation, or an address of data for which the operation is performed,
wherein the under layer includes a first metal nitride layer having a NaCl crystal structure and a second metal nitride layer containing a light metal,
wherein the semiconductor memory is part of the memory unit in the microprocessor.

3. An electronic device comprising semiconductor memory, wherein the semiconductor memory comprises:
an under layer;
a first magnetic layer located over the under layer and having a variable magnetization direction;
a tunnel barrier layer located over the first magnetic layer; and
a second magnetic layer located over the tunnel barrier layer and having a pinned magnetization direction; and
a data storage system which includes:
a storage device configured to store data and conserve stored data regardless of power supply;
a controller configured to control input and output of data to and from the storage device according to a command inputted form an outside;
a temporary storage device configured to temporarily store data exchanged between the storage device and the outside; and
an interface configured to perform communication between at least one of the storage device, the controller and the temporary storage device and the outside,
wherein the under layer includes a first metal nitride layer having a NaCl crystal structure and a second metal nitride layer containing a light metal,
wherein the semiconductor memory is part of the storage device or the temporary storage device in the data storage system.

4. An electronic device comprising semiconductor memory, wherein the semiconductor memory comprises:
an under layer;
a first magnetic layer located over the under layer and having a variable magnetization direction;
a tunnel barrier layer located over the first magnetic layer; and
a second magnetic layer located over the tunnel barrier layer and having a pinned magnetization direction; and
a memory system which includes:
a memory configured to store data and conserve stored data regardless of power supply;
a memory controller configured to control input and output of data to and from the memory according to a command inputted form an outside;
a buffer memory configured to buffer data exchanged between the memory and the outside; and
an interface configured to perform communication between at least one of the memory, the memory controller and the buffer memory and the outside,
wherein the under layer includes a first metal nitride layer having a NaCl crystal structure and a second metal nitride layer containing a light metal,
wherein the semiconductor memory is part of the memory or the buffer memory in the memory system.
